(19) United States
(12) Patent Application Publication
(10) Pub. No.: US 2011/0157809 A1
(43) Pub. Date: Jun. 30, 2011

(54) MAINBOARD AND SHUTDOWN MANAGEMENT METHOD

(75) Inventors: WEI SHAO, Shenzhen City (CN); YU-GANG ZHANG, Shenzhen City (CN)

(73) Assignees: HONG FU JIN PRECISION INDUSTRY (ShenZhen) CO.,LTD., Shenzhen City (CN); HON HAI PRECISION INDUSTRY CO., LTD., Tu-Cheng (TW)

(21) Appl. No.: 12/953,245

(22) Filed: Nov. 23, 2010

(30) Foreign Application Priority Data
Dec. 30, 2009 (CN) 200910312709.4

(51) Int. Cl. G06F 1/00; H05K 7/02

(52) U.S. Cl. 361/679.31

(57) ABSTRACT

A mainboard and a shutdown management method to determine whether a shutdown procedure of the mainboard is executed normally. The mainboard set predetermined status parameters of a plurality of elements of the mainboard. Upon detecting that the mainboard is in the shutdown procedure, the mainboard determines whether the shutdown procedure is executed normally by comparing status parameters of the plurality of elements and the predetermined status parameters.

### BACKGROUND

1. Technical Field

Embodiments of the present disclosure relate to mainboard operation management, and more particularly to a mainboard and method of shutdown management.

2. Description of Related Art

The power supply management interface (PSMI) is usually used as a management interface of the power supply in a computer. The power supply management interface can detect a plurality of parameters of the power supply in a computer by an I2C bus, such as a voltage and operation temperature of the power supply. However, the PSMI is not suitable to be installed in a low level computer because of a higher cost. Thus, a mainboard can not determine whether the low level computer is in abnormal shutdown by detecting the number of parameters of the power supply.

### BRIEF DESCRIPTION OF THE DRAWINGS

FIG. 1 is a block diagram of one embodiment of a mainboard.

FIG. 2 is a flowchart illustrating one embodiment of a shutdown management method using the mainboard.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

In general, the word “module” as used herein, refers to logic embodied in hardware or firmware, or to a collection of software instructions, written in a programming language, such as, for example, Java, C, or Assembly. One or more software instructions in the module may be embedded in firmware, such as an EPROM. It will be appreciated that module may comprise connected logic units, such as gates and flip-flops, and may comprise programmable units, such as programmable gate arrays or processors. The module described herein may be implemented as either software and/or hardware module and may be stored in any type of computer-readable medium or other computer storage device.

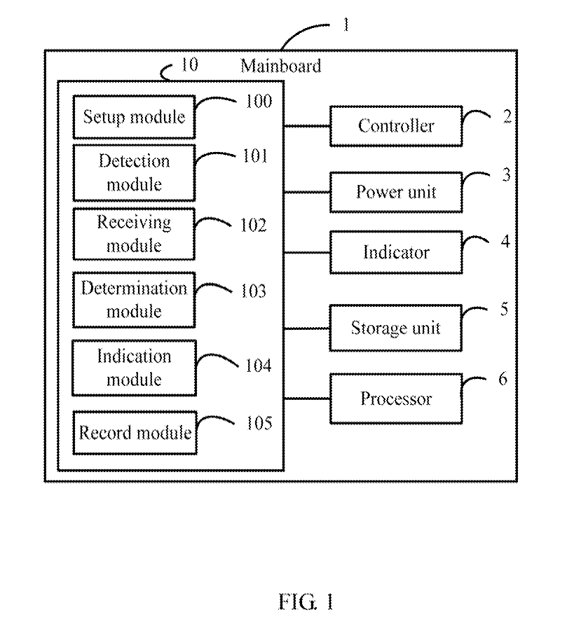

FIG. 1 is a block diagram of one embodiment of a mainboard 1. The mainboard 1 includes a controller 2, a power unit 3, an indicator 4, a storage unit 5, at least one processor 6 and a monitor system 10. The monitor system 10 includes a setup module 100, a detection module 101, a receiving module 102, a determination module 103, an indication module 104, and a record module 105.

The controller 2 is operable to monitor the statuses of a plurality of elements of the mainboard 1 and to save status parameters of the plurality of elements of the mainboard 1 to the storage unit 5. In some embodiment, the number of elements of the mainboard may be at least one cooling fan, at least one flash memory, RAM, ROM, cache, at least one processor 6 and the power unit 3.

For example, the controller 2 monitors the status of the operation voltage of the power unit 3 and saves the operation voltage to the power unit 3, such as 12 voltages. In addition, the controller 2 monitors the status of the operation temperature of the power unit 3 and saves the operation temperature to the power unit 3, such as 40 degree Celsius.

The at least one processor 6 may execute one or more programs stored in the storage unit 5 to provide functions for the setup module 100, the detection module 101, the receiving module 102, the determination module 103, the indication module 104, and the record module 105. The at least one processor 6, as an example, may include a CPU, a math coprocessor, or a shift register.

The storage unit 5 electronically connects to the controller 2, the power unit 3, the indicator 4, the at least one processor 6 and the monitor system 10. The storage unit 5 is operable to store many kinds of data, such as the at least one status parameter of the plurality of elements of the mainboard 1, a customization function code of the mainboard 1 and computerized codes of the monitor system 10. The storage unit 5 may include at least one flash memory, RAM, ROM, or cache.

The setup module 100 is operable to set predetermined status parameters for the number of elements of the mainboard 1. The predetermined status parameters may be a permitted highest temperature of the at least one processor 6. Upon the condition that the temperature of the at least one processor 6 reaches the permitted highest temperature, the controller 2 controls the mainboard 1 to execute a shutdown procedure.

The predetermined status parameters may be a permitted speed of the least one cooling fan installed on the at least one processor 6. Upon the condition that a speed of the at least one cooling fan equals to the permitted speed, the controller 2 controls the mainboard 1 to execute the shutdown procedure. The predetermined status parameters may be a highest permitted temperature of the storage unit 5. If the temperature of the storage unit 5 reaches the highest permitted temperature, the controller 2 controls the mainboard 1 to execute the shutdown procedure.

The detection module 101 is operable to determine whether the mainboard 1 is in the shutdown procedure by a power signal generated from the power unit 3. The power signal may be a power good signal. In some embodiments, upon the condition that the detected power good signal falling below a power threshold, the detection module 101 determines that the mainboard 1 is in the shutdown status.

The receiving module 102 is operable to receive the status parameters of the plurality of elements of the mainboard 1 from the controller 2 when the mainboard 1 is in the shutdown procedure.

The determination module 103 is operable to determine whether the status parameters received from the receiving module 102 are the same as the predetermined status parameters. If the received status parameters are the same as the predetermined status parameters, the determination module 103 determines that the shutdown procedure is executed normally. In addition, the determination module 103 sends a normal signal to the indication module 104.

If the received status parameters are different from the predetermined status parameters, the determination module 103 determines that the shutdown procedure is executed abnormally. In addition, the determination module 103 sends an abnormal status signal to the indication module 104.

Upon receiving the abnormal status signal from the determination module 103, the indication module 104 sends the indication signal to the indicator 4. The indicator 4 then outputs an abnormal message indicating that the shutdown procedure is executed abnormally. In some embodiments, the indicator 4 may be a speaker or a light indicator. The abnormal message may be an audio signal or a light signal.

The record module 105 is configured to save the status parameters received from the receiving module 102 in the storage unit 5. The received status parameters may be saved in a normal log file or an abnormal log file. Upon the condition that the received status parameters are the same as the predetermined status parameters, the record module 105 saves the received status parameters in the normal log file. Upon the condition that the received status parameters are different from the predetermined status parameters, the record module 105 saves the received status parameters in the abnormal log file.

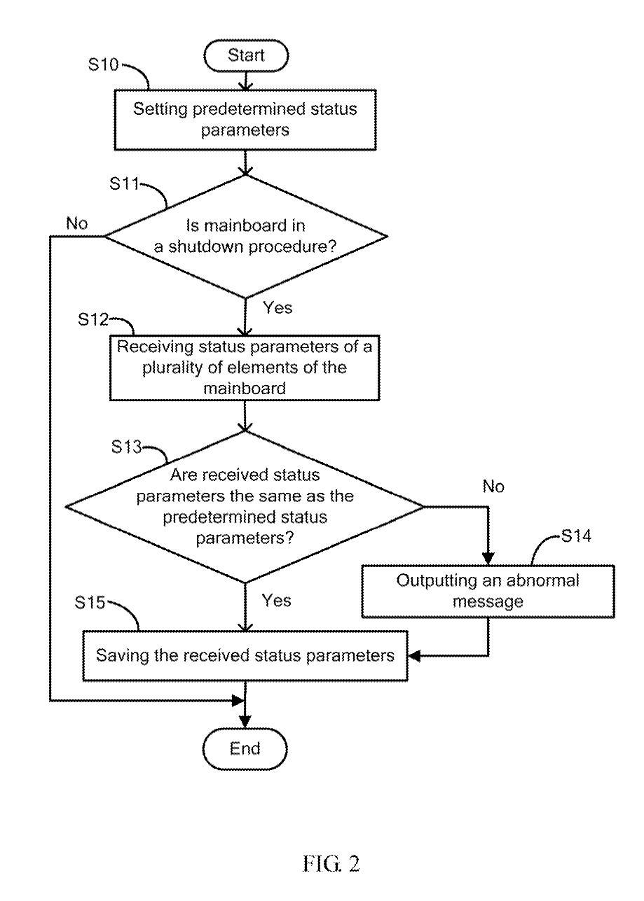

FIG. 2 is a flowchart illustrating one embodiment of a shutdown management method. Depending on the embodiment, additional blocks may be added, others deleted, and the ordering of the blocks may be changed.

In block S10, the setup module 100 sets predetermined status parameters of a plurality of elements of the mainboard 1. The plurality of elements of the mainboard may include at least one cooling fan, at least one flash memory, RAM, ROM, cache, at least one processor and the power unit.

In block S11, the detection module 101 determines whether the mainboard 1 is in a shutdown procedure basing on a power signal generated from the power unit 3. If the mainboard 1 is in the shutdown procedure, the process goes to block S12. If the mainboard 1 is not in the shutdown procedure, the process ends.

In block S12, the receiving module 102 receives status parameters of the number elements of the mainboard 1 from the controller 2 when the mainboard 1 is in the shutdown procedure.

In block S13, the determination module 103 determines whether the status parameters received from the receiving module 102 are the same as the predetermined status parameters. If the received status parameters are the same as the predetermined status parameters, the process goes to block S15. If the received status parameters are different from the predetermined status parameters, the process goes to block S14.

In block S14, the indication module 104 sends the indication signal to the indicator 4 to output an abnormal message indicating that the mainboard 1 has executed the shutdown procedure abnormally.

In block S15, the record module 105 saves the received status parameters in the storage unit 5. The received status parameters may be saved in a normal log file or an abnormal log file. Upon the condition that the received status parameters are the same as the predetermined status parameters, the record module 105 saves the received status parameters the normal log file. Upon the condition that the received status parameters are different from the predetermined status parameters, the record module 105 saves the received status parameters in the abnormal log file.

Although certain embodiments of the present disclosure have been specifically described, the present disclosure is not to be construed as being limited thereto. Various changes or modifications may be made to the present disclosure without departing from the scope and spirit of the present disclosure.

What is claimed is:

1. A mainboard comprising a plurality of elements, comprising:
a storage unit;
a power unit;
at least one processor;
a controller configured to monitor statuses of the plurality of elements of the mainboard;
one or more programs stored in the storage unit and being executable by the at least one processor;
a setup module to set predetermined status parameters of the plurality of elements of the mainboard to execute a normal shutdown procedure;
a detection module to determine whether the mainboard is in a shutdown procedure basing on a power signal generated from the power unit;
a receiving module to receive status parameters of the plurality of elements of the mainboard from the controller upon the condition that the mainboard is in the shutdown procedure;
a record module to save the received status parameters in the storage unit; and
a determination module to determine that the shutdown procedure being executed normally upon the condition that the received status parameters are the same as the predetermined status parameters.

2. The mainboard of claim 1, wherein the determination module determines that the shutdown procedure is executed abnormally upon the condition that the received status parameters are different from the predetermined status parameters.

3. The mainboard of claim 2, the mainboard further comprises an indication module to send an indication signal to an indicator upon receiving an abnormal status signal from the determination module.

4. The mainboard of claim 3, wherein the indicator outputs an abnormal message upon receiving the indication signal.

5. The mainboard of claim 4, wherein the abnormal message is a voice message or a light message.

6. A shutdown management method for a mainboard, the mainboard comprising a power unit, at least one processor, a storage unit and a controller, the method comprising:
setting predetermined status parameters of a plurality of elements of the mainboard to execute a shutdown procedure;
determining whether the mainboard is in the shutdown procedure basing on a power signal generated from the power unit;
receiving status parameters of the plurality of elements of the mainboard from the controller upon the condition that the mainboard is in the shutdown procedure; and
determining that the shutdown procedure being executed normally upon the condition that the received status parameters are the same as the predetermined status parameters.

7. The method of claim 6, further comprising:
determining that the shutdown procedure being executed abnormally upon the condition that the received status parameters are different from the predetermined status parameters.

8. The method of claim 7, further comprising:
outputting an abnormal message upon the condition that the shutdown procedure is executed abnormally.

9. The method of claim 8, wherein the abnormal message is a voice message or a light message.

10. A storage medium having stored thereon instructions that, when executed by a processor, causes the processor to perform a shutdown management method for a mainboard, the mainboard comprising a power unit, at least one processor, a storage unit and a controller, the method comprising:
setting predetermined status parameters of a plurality of elements of the mainboard to execute a shutdown procedure;
determining whether the mainboard is in the shutdown procedure basing on a power signal generated from the power unit;
receiving status parameters of the plurality of elements of the mainboard from the controller upon the condition that the mainboard is in the shutdown procedure; and;
determining that the shutdown procedure being executed normally upon the condition that the received status parameters are the same as the predetermined status parameters.

11. The storage medium of claim 10, wherein the method further comprising determining that the shutdown procedure being executed abnormally upon the condition that the received status parameters are different from the predetermined status parameters.

12. The storage medium of claim 11, wherein the method further comprising:
outputting an abnormal message upon the condition that the shutdown procedure is executed abnormally.

13. The storage medium of claim 12, wherein the abnormal message is a voice message or a light message.
